(19) United States
(12) Patent Application Publication
(10) Pub. No.: US 2014/0218887 A1
(43) Pub. Date: Aug. 7, 2014

(54) HIGH-VOLTAGE SWITCHING DEVICE WITH ENERGY-SUPPLY DEVICE

(71) Applicant: MASCHINENFABRIK REINHAUSEN GMBH, Regensburg (DE)

(72) Inventors: Wladimir Bauer, Regensburg (DE); Anatoli Saveliev, Zeitlarn (DE)

(21) Appl. No.: 14/239,820

(22) PCT Filed: Oct. 18, 2012
(86) PCT No.: PCT/EP2012/070679

§ 371 Date: Feb. 22, 2014

(30) Foreign Application Priority Data
Oct. 24, 2011 (DE) 10 2011 120 526.1

(51) Int. Cl. H05K 9/00

(52) U.S. Cl. CPC H05K 9/002
USPC 361/816

(57) ABSTRACT

The present invention relates to a high-voltage switching device with energy-supply device according to the preamble of the first claim. The general inventive idea consists in locating at least two oppositely wound first conductor loops in a first recessed region on the outer side of an EMC-secure housing for a high-voltage switching device, the outer side of which is designed as a screening plate, and that these loops interact electrically with at least two other second conductor loops, also wound in opposite directions, which are disposed in a second recessed region on the inside of the EMC-secure housing, also designed as a screening plate, such that due to the different directions of the windings of the first two conductive loops and the second two conductor loops, the current flows in opposite directions in the windings of the first and second two conductor loops, and thus each produces an opposing magnetic field, and these fields are additively superimposed such that the eddy currents on the outside and inside of the EMC-secure housing compensate for one another, and thus an inductive energy supply system will be created through the EMC-secure housing.

The present invention relates to a high-voltage switching apparatus with an power supply according to the preamble of the first claim.

The supply of controlling, regulating and measuring devices in high-voltage switching apparatuses with electrical energy is usually connected with heightened technical outlay for dielectric screening and field control. In addition, the special demands on electrical insulation significantly restrict the choice of power supplies.

Here, a solution conceivable, in principle would be inductive energy transfer. The functioning of this technology corresponds with the principle of functioning of a conventional transformer with a very large air gap between a primary winding acting as a transmitter and a secondary winding acting as a receiver. Due to the absence of an iron core of the transformer inductive energy transfer offers numerous advantages with respect to the case of use. Small dimensions and low costs as well as elimination of the cable between transmitter and receiver favor use of this technology in the energy supply of controlling, regulating and measuring devices. The technical principles of inductive energy transfer have been known for many years and are described in, for example, an article ‘Kontaktlose Energieübertragung’ of Peter Wambsganss and Nejila Parpour.

A high-voltage switching apparatus, namely a tap changer with semiconductor switching elements for uninterrupted changeover between winding taps of a tapped transformer, is described in DE 10 2009 017 197 A1 of the applicant [US 2012/0025789]. In that case, provided in the load changeover switch of the tap changer are electronic power semiconductor switching elements which are screened to the outside with respect to electromagnetic compatibility, EMC for short, by an EMC-proof housing. The energy supply of these semiconductor components represents, according to the prior art, an ever-present and much-discussed problem. DE 10 2009 017 197 A1 proposes for that purpose a voltage supply of the semiconductor elements from the respective tap voltage of the regulating winding of the power transformer, which requires electrical cable guides involving technical complication to screen. In principle, from the technical aspect it is not desirable to have to provide conductor guides of that kind in the environment of components loaded with high voltage.

The object of the present invention is therefore to provide a high-voltage switching apparatus which an power supply in which it may be possible to dispense with electrical cable guides for the purpose of energy supply of the high-voltage switching apparatus in the environment of components loaded with high voltage.

This object is fulfilled by a high-voltage switching apparatus with an power supply with the features of the first claim. The subclaims in that case relate to particularly advantageous developments of the invention.

The general inventive idea in that case consists of arranging at the outer side, which is formed as a screening plate, of an EMC-proof housing of a high-voltage switching apparatus, at least two conductor loops in the region of a first recess provided at the outer side, which loops are wound in opposite sense and electrically co-operate with at least two further, inner conductor loops, which are similarly wound in opposite sense and which are arranged in the region of a second recess provided at the inner side, which is similarly constructed as a screening plate, of the EMC-proof housing, in such a manner that by virtue of the different winding sense of the windings of the outer conductor loops and the inner conductor loops the current flow in the respective windings of the outer and inner conductor loops is similarly oppositely directed and thus a respective oppositely directed magnetic field is built up, which is correspondingly additively superimposed so that the eddy currents at the outer side and inner side of the EMC-proof housing are mutually compensating and thus an inductive power supply through the EMC-proof housing is created. A purely inductive power supply is, in fact, already known from the prior art, but these known devices are not suitable for transporting energy purely inductively through an EMC-proof screening. This intention has consistently failed in the prior art due to the eddy currents which arise in the metallic screening plates and for which compensation could not be provided. Only the special conductor loop arrangement in conjunction with the provided recesses in the screening plates makes possible a purely inductive power supply in the environment of an EMC-proof screening.

The invention will be explained in more detail in the following by way of example on the basis of drawings, in which:

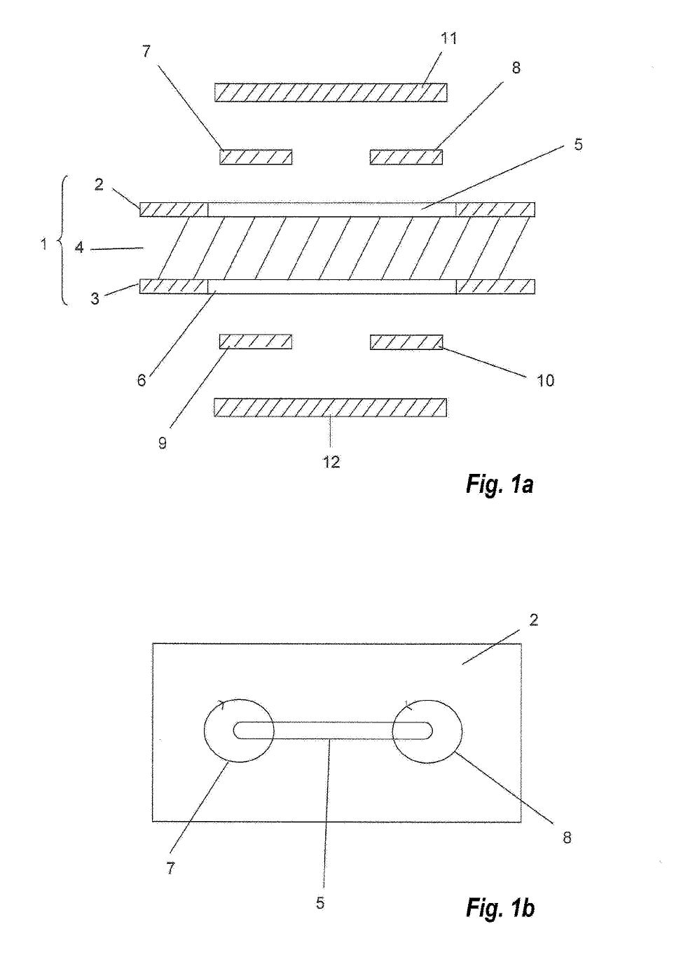

FIGS. 1a and 1b show a side schematic illustration of a high-voltage switching apparatus according to the invention with an inductive power supply and the plan view thereof and

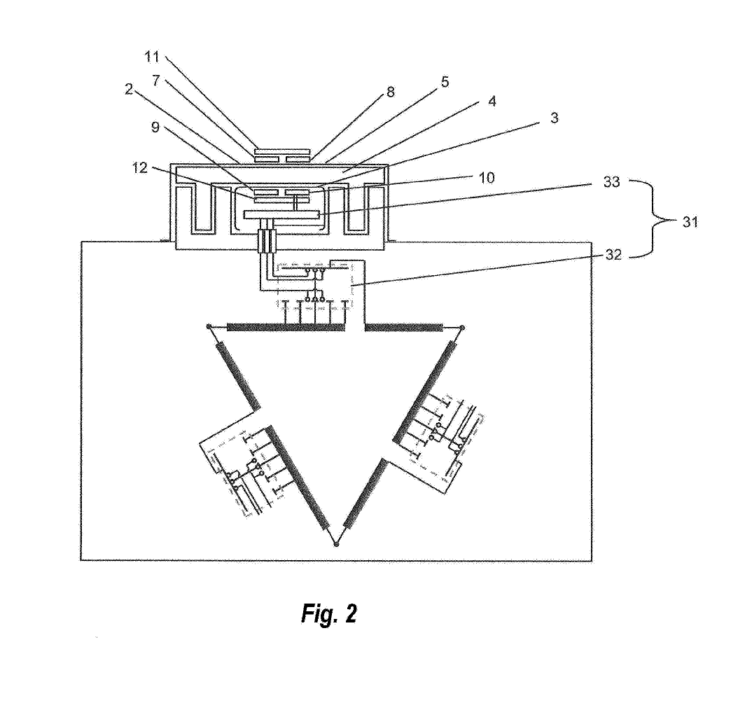

FIG. 2 shows a preferred form of embodiment of a high-voltage switching apparatus according to the invention with an inductive power supply.

FIG. 1a shows the side schematic layout of a high-voltage switching apparatus according to the invention with an inductive power supply, wherein the high-voltage switching apparatus is not, however, shown in this illustration. The high-voltage switching apparatus is enclosed by an EMC-proof housing 1 of layered construction which consists an outer screening plate forming an outer side 2, an inner screening plate forming an inner side 3 and an electrical insulating medium 4 disposed therebetween. In that case the outer side 2 and the inner side 3 are formed from a metallic material, for example of aluminum. In addition, respective longitudinally extending recesses 5 and 6 are formed in the outer side 2 and the inner side 3, in the corresponding regions of which recesses are provided two oppositely wound conductor loops 7 and 8 or 9 and 10 substantially opposite one another. In that case, the two outer oppositely wound conductor loops 7 and 8 are constructed as a primary winding, i.e. as a transmitter, of a transformer, whereagainst the two oppositely wound inner conductor loops 9 and 10 are constructed as a secondary winding, thus a receiver, of the transformer. In addition, the two outer conductor loops 7 and 8 are covered on the side, which is opposite the outer side 2, by a first ferrite plate 11, whilst the two inner conductor loops 9 and 10 symmetrical therewith are covered on the side, which is opposite the inner side 3, by a second ferrite plate 12. The oppositely wound conductor loops 7 and 8 or 9 and 10 can, for example, be identically constructed coils each with 20 windings, which can be made from copper wire. The number of windings in the conductor loops 7 to 10 can in that case vary within the scope of the invention in wide ranges, i.e. from 1 to 200 windings. However, it is to be observed in the design of the components that the respective windings of the inner conductor loops 7 and 8 or of the outer conductor loops 9 and 10 are constructed symmetrically with respect to one another and in each instance have the same number of windings. The conductor loops on the transmitter side and receiver side (9 and 7 or 8 and 10), thereagainst, do not necessarily have to be of symmetrical construction. The translation ratio of the transfer path can be influenced by selection of the winding numbers on the transmitter side and receiver side.

If the outer conductor loops 7 and 8 acting as primary winding of a transformer are acted on by a voltage changing over time then due to the windings of opposite sense of the conductor loops 7 and 8 or 9 and 10 with respect to one another a correspondingly oppositely directed current flow within the individual conductor loops 7 and 8 or 9 and 10 and thus ultimately an oppositely directed magnetic field of the conductor loops 7 to 10 with respect to one another arises. As a consequence thereof also the respectively arising eddy currents in the outer side 2 and the inner side 3 are correspondingly oppositely directed.

According to the invention, due to this arrangement as a consequence of the additive superimposition of the eddy currents lower eddy current losses arise than in arrangements known from the prior art. A technical capability of realization of inductive energy transferred by means of the selectively controlled eddy currents through the EMC-proof housing 1 is thus created.

FIG. 1b shows a plan view of the arrangement described in FIG. 1a, but without the ferrite plate 11 shown in FIG. 1a. As can be seen in this illustration, the outer conductor loops 7 and 8 are provided in the region of the longitudinal recess 5 of the outer side of the housing 1. The winding sense of the outer conductor loops 7 and 8, which here are illustrated by way of example by only a single winding, is here indicated by arrows. According to an equally conceivable form of embodiment of the invention it would also be possible to provide several conductor coils, i.e. three, four or five, instead of the two conductor loops 7 and 8, which are shown here, along the recess 5. In this case, a corresponding number of co-operating conductor loops would similarly have to be arranged on the opposite inner side 3 (not shown here) of the housing 1 substantially opposite to the outer conductor loops.

Moreover, according to the essence of the present invention it is not absolutely necessary for the corresponding recesses 5 and 6 to extend longitudinally; rather, it is also conceivable to form these recesses 5 and 6 to be cruciform of angular. However, the conductor loops 7 and 8 or 9 and 10 have to be arranged as described above at the recesses 5 and 6 so that the resulting eddy currents in the EMC-proof housing 1 are thereby mutually compensating and a high level of efficiency of the transmission path is achieved in the result.

FIG. 2 shows a preferred form of embodiment of the invention in which the high-voltage switching apparatus according to the invention with inductive power supply and EMC-proof housing 1 is fastened to a transformer housing 30. The transformer can be, for example, a power transformer such as known from the prior art. A high-voltage switching apparatus 31, namely a tap changer with semiconductor switching elements for uninterrupted changeover between the winding taps of the power transformer illustrated here is shown in the interior of the transformer housing 30, as is basically described in DE 10 2009 017 197 A1. Reference is made to DE 10 2009 017 197 A1 for the basic description of the tap changer and the content thereof is hereby made subject of this application. The high-voltage switching apparatus 31 comprises a mechanical contact system 32 and an electronic power load changeover switch 33. However, in departure from DE 10 2009 017 197 A1 the energy supply of the electronic power load changeover switch 33 takes place in the illustration of FIG. 2 not from the tap voltage of the regulating winding of the power transformer, but in particularly simple manner by means of the device according to the invention, which is described in FIGS. 1a and 1b, for inductive coupling of energy into the high-voltage switching apparatus 31.

1. A high-voltage switching apparatus with power supply, wherein the high-voltage switching apparatus comprises an EMC-proof housing consisting of an electrically conductive outer screening plate, a similarly electrically conductive inner screening plate and an electrical insulating medium disposed between the outer and inner screening plates, wherein
energy-consuming consumers are provided in the interior of the high-voltage switching apparatus and
the energy-consuming consumers can be acted on electrically by means of the power supply, characterized in that
the power supply has at least two oppositely wound outer conductor loops at the outer sides constructed as a screening plate of the EMC-proof housing of the high-voltage switching apparatus in the region of a first recess provided at the outer side and
the power supply has at least two further similarly oppositely wound inner conductor loops in the region of a second recess provided at the inner side, which is similarly constructed as a screening plate, of the EMC-proof housing so that the outer and inner conductor loops co-operate in such a manner that through the different winding sense of the windings of the outer conductor loops and the inner winding loops the current flow in the respective windings of the outer and inner two conductor loops is also in opposite direction and thus a respective oppositely directed magnetic field is built up, which is correspondingly additively superimposed so that the eddy currents at the outer side and inner side of the EMC-proof housing are mutually compensating and thus an inductive power supply through the EMC-proof housing is created.

2. The high-voltage switching apparatus with power supply according to claim 1, wherein the recess extends longitudinally in the corresponding inner or outer side, respectively.

3. The high-voltage switching apparatus with power supply according to claim 1, wherein the recess is formed in the corresponding inner or outer side to be respectively cruciform.

4. The high-voltage switching apparatus with power supply according to claim 1, wherein the outer conductor loops are at least partly enclosed by a ferrite plate on the side opposite the outer side.

5. The high-voltage switching apparatus with power supply according to claim 1, wherein the inner conductor loops are at least partly enclosed by a ferrite plate on the side opposite the inner side.

6. The high-voltage switching apparatus with power supply according to claim 1, wherein the high-voltage switching apparatus is a tap changer with semiconductor switching elements for uninterrupted switching over between winding taps of a power transformer.

7. The high-voltage switching apparatus with power supply according to claim 1, wherein the high-voltage switching apparatus comprises a mechanical contact system and an electronic power load changeover switch.

8. The high-voltage switching apparatus with power supply according to claim 1, wherein the high-voltage switching apparatus together with inductive power supply with EMC-proof housing is fastened to a transformer housing.
